(19) United States
(12) Patent Application Publication
(10) Pub. No.: US 2025/0083272 A1
(43) Pub. Date: Mar. 13, 2025

(54) WAFER PLACEMENT TABLE

(71) Applicant: NGK INSULATORS, LTD., Nagoya-City (JP)

(72) Inventors: Keita MINE, Chita-District (JP); Yohei KAJIURA, Nagoya-City (JP)

(73) Assignee: NGK INSULATORS, LTD., Nagoya-City (JP)

(21) Appl. No.: 18/665,644

(22) Filed: May 16, 2024

Related U.S. Application Data
(63) Continuation of application No. PCT/JP2023/033249, filed on Sep. 12, 2023.

(51) Int. Cl. B23Q 11/14; B23Q 3/02; B23Q 11/10

(52) U.S. Cl. CPC B23Q 11/141; B23Q 3/02; B23Q 11/10

(57) ABSTRACT

A wafer placement table includes a ceramic plate having a wafer placement surface on its upper surface, a cooling plate on a lower surface of the ceramic plate, a refrigerant flow path in the cooling plate, and an insulating hole located beside the refrigerant flow path in the cooling plate and extending from a lower surface of the cooling plate to a ceiling located higher than 2/3 of a height of the refrigerant flow path from its bottom.

### BACKGROUND OF THE INVENTION

### 1. Field of the Invention

The present invention relates to a wafer placement table.

### 2. Description of the Related Art

A known wafer placement table includes a ceramic plate having a wafer placement surface on its upper surface, a cooling plate on a lower surface of the ceramic plate, and a refrigerant flow path in the cooling plate. For example, PTL 1 discloses a wafer placement table of this type that includes a cooling plate having a first insulating layer under the refrigerant flow path and a second insulating layer connected to the first insulating layer and extending to 1/3 to 2/3 of the height of the refrigerant flow path on both sides of the refrigerant flow path. In PTL 1, the first and second insulating layers cover the refrigerant flow path to provide insulation from the lower surface of the cooling plate. This allows the refrigerant to absorb less heat from the lower surface side of the cooling plate, improving the cooling effect of the ceramic plate.

### CITATION LIST

### Patent Literature

PTL 1: Japanese Unexamined Patent Application

Publication No. 2021-141228

### SUMMARY OF THE INVENTION

A wafer placement table is required to have a wafer placement surface having a predetermined temperature distribution in some cases. For example, for a wafer placement table including an electrostatic chuck that electrostatically attracts wafers, uniform temperature distribution in the wafer placement surface may be a more important performance factor than an improvement in cooling effect. However, PTL 1, which can improve the cooling effect, does not discuss adjustment of the temperature distribution in the wafer placement surface.

The present invention was made to solve the above-described problem, and the main object thereof is to allow the wafer placement surface to have preferable temperature distribution.

[1] A wafer placement table of the present invention includes: a ceramic plate having a wafer placement surface on its upper surface; a cooling plate on a lower surface of the ceramic plate; a refrigerant flow path in the cooling plate; and an insulating hole located beside the refrigerant flow path in the cooling plate and extending from a lower surface of the cooling plate to a ceiling located higher than 2/3 of a height of the refrigerant flow path from its bottom.

The wafer placement table has an insulating hole located beside the refrigerant flow path, and the insulating hole extends from the lower surface of the cooling plate to the ceiling located higher than 2/3 of the height of the refrigerant flow path from the bottom. When the wafer placement table, which includes a ceramic plate having a wafer placement surface on its upper surface, a cooling plate on a lower surface of the ceramic plate, and a refrigerant flow path in the cooling plate, receives heat at the wafer placement surface, the refrigerant in the refrigerant flow path extracts heat through the ceiling of the refrigerant flow path and also through the side surfaces of the refrigerant flow path. The heat flux in the cooling plate at that time tends to be relatively large at a portion located beside the refrigerant flow path and higher than 2/3 of the height of the refrigerant flow path from the bottom, depending on the material of the cooling plate. If the portion where the heat flux is large has the insulating hole, the hole functions as an insulating layer and efficiently reduces heat extraction around it. Thus, the insulating hole formed at a position corresponding to a portion of the wafer placement surface where the temperature is lower than a desired temperature when the insulating hole is not present, for example, can reduce heat extraction at the portion, bringing the temperature distribution in the wafer placement surface closer to the desired temperature distribution.

[2] In the wafer placement table according to the present invention (the wafer placement table according to [1] above), a distance between the ceiling of the insulating hole and an upper surface of the cooling plate may be 1 mm or more. When the distance is 1 mm or more, the wafer placement table is less likely to be damaged.

[3] In the wafer placement table according to the present invention (the wafer placement table according to [1] or [2] above), the insulating hole may be located between passages of the refrigerant flow path. The cooling plate may have one refrigerant flow path or two or more refrigerant flow paths. The insulating hole may be located between passages of one refrigerant flow path or between two or more refrigerant flow paths.

[4] In the wafer placement table according to the present invention (the wafer placement table according to any one of [1] to [3] above), the ceiling of the insulating hole may have a step or a slope. The step or slope in the ceiling raises the ceiling of the portion that requires further less heat extraction, bringing the temperature distribution in the wafer placement surface closer to the desired temperature distribution.

[5] In the wafer placement table according to the present invention (the wafer placement table according to any one of [1] to [4] above), the cooling plate may have a thermal conductivity of 100 W/(m·K) or higher. As the thermal conductivity of the cooling plate increases, when the wafer placement surface receives heat, the heat flux at a portion located beside the refrigerant flow path and higher than 2/3 of the height of the refrigerant flow path from the bottom (formation portion of the insulating hole) tends to be higher than that at the other portions, allowing the insulating hole to exhibit high efficiency in reducing heat extraction.

[6] In the wafer placement table according to the present invention (the wafer placement table according to any one of [1] to [5] above), the insulating hole may be located at a position corresponding to a portion of the wafer placement surface where a temperature is locally low when the insulating hole is not present. This can reduce heat extraction at the portion of the wafer placement surface where the temperature is locally low, improving the heat uniformity of the wafer placement surface. The “portion of the wafer placement surface where the temperature is locally low when the insulating hole is not present” may be determined by actually using a wafer placement table before formation of the insulating hole or by using a wafer placement table that has the insulating hole filled with a material of the cooling plate.

### BRIEF DESCRIPTION OF THE DRAWINGS

FIG. 1 is a vertical cross-sectional view of a wafer placement table 10.

FIG. 2 is a plan view of the wafer placement table 10.

FIG. 3 is a cross-sectional view taken along A-A in FIG. 1.

FIG. 4 is a partial magnified view of FIG. 1 including an insulating hole 40.

FIG. 5 is a partial magnified view of a cross-section taken along B-B in FIG. 2 including the insulating hole 40.

FIGS. 6A and 6B illustrate a process of producing the wafer placement table 10.

FIG. 7 illustrates another example of the insulating hole 40 and is a partial magnified view corresponding to FIG. 4.

FIG. 8 illustrates another example of the insulating hole 40 and is a partial magnified view corresponding to FIG. 4.

FIG. 9 illustrates another example of the insulating hole 40 and is a partial magnified view corresponding to FIG. 5.

FIG. 10 illustrates another example of the insulating hole 40 and is a partial magnified view corresponding to FIG. 5.

FIG. 11 illustrates another example of the insulating hole 40 and is a partial magnified view corresponding to FIG. 4.

FIG. 12 illustrates another example of the insulating hole 40 and is a partial magnified view corresponding to FIG. 4.

FIG. 13 is an explanatory view illustrating an example of heat flux distribution in a vertical cross-section of a cooling plate.

### DETAILED DESCRIPTION OF THE INVENTION

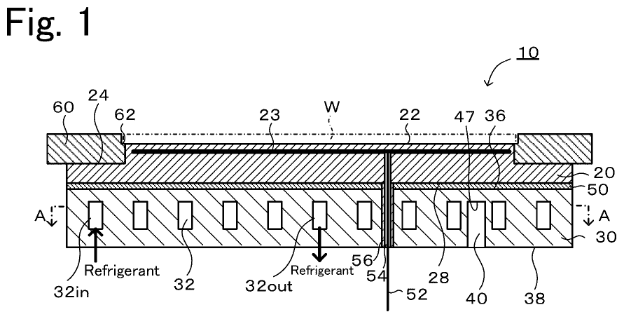

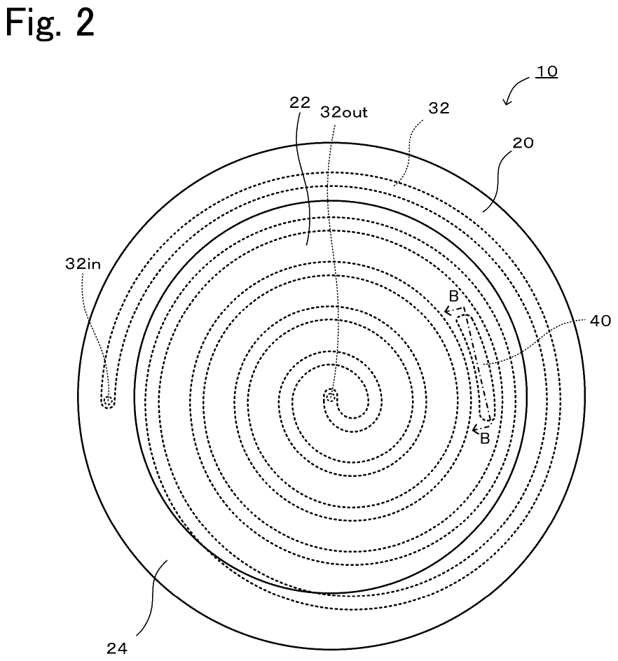

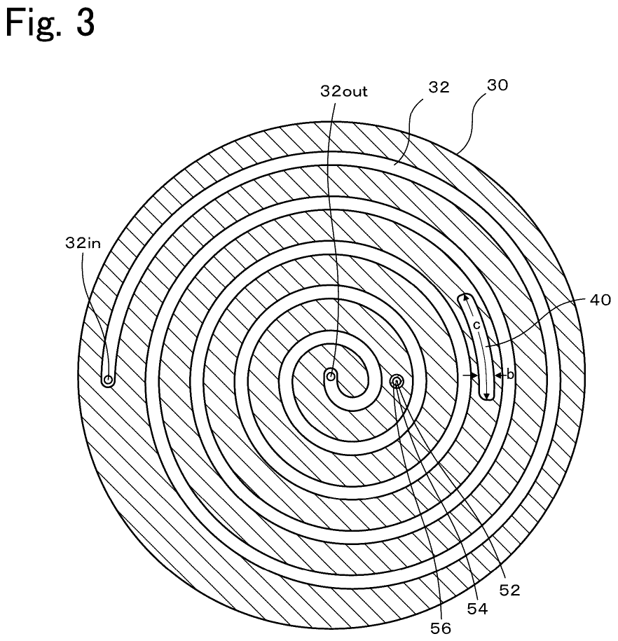

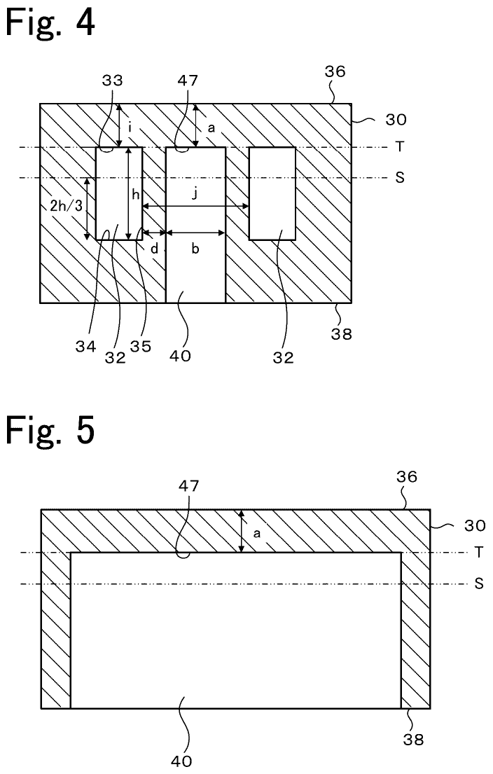

Next, a preferable embodiment of the present invention will be described with reference to the drawings. FIG. 1 is a vertical cross-sectional view of a wafer placement table 10 (cross-sectional view of the wafer placement table 10 taken along the plane including the central axis of the wafer placement table 10). FIG. 2 is a plan view of the wafer placement table 10. FIG. 3 is a cross-sectional view of FIG. 1 taken along A-A. FIG. 4 is a partial magnified view of FIG. 1 including an insulating hole 40. FIG. 5 is a partial magnified view of a cross-section taken along B-B in FIG. 2 including the insulating hole 40.

The wafer placement table 10 is intended to perform CVD, etching, or the like on a wafer W by using plasma. The wafer placement table 10 includes a ceramic plate 20, a cooling plate 30, and a joining layer 50.

The ceramic plate 20 is made of a ceramic material represented by alumina, aluminum nitride, or the like. The ceramic plate 20 has a wafer placement surface 22, an electrostatic electrode 23, and a focus-ring placement surface 24. Hereinafter, focus ring may be abbreviated to “FR”.

The wafer placement surface 22 is a circular surface and provided on an upper surface of the ceramic plate 20. The wafer W is to be placed on the wafer placement surface 22. The wafer placement surface 22 is provided with an annular seal band, which is not illustrated, along the outer edge thereof. The area surrounded by the seal band has a plurality of round small projections provided over the entirety of the area. The seal band and the round small projections are of the same height, which is several μm to several 10 s of μm, for example.

The electrostatic electrode 23 is a planar mesh electrode or a plate electrode and is connected to a DC power source (not illustrated) through a power feed terminal 52. When DC voltage is applied across the electrostatic electrode 23 from the DC power source, the wafer W is attracted and fixed to the wafer placement surface 22 (specifically, the upper surface of the seal band and the upper surfaces of the small circular projections) by the electrostatic attraction. When the application of DC voltage is stopped, the wafer W is not attracted and fixed to the wafer placement surface 22. The power feed terminal 52 extends through an insulating tube 56 in a through hole of a terminal hole 54 extending vertically through the cooling plate 30 and the bonding layer 50 and further extends from the lower surface 28 of the ceramic plate 20 to the lower surface of the electrostatic electrode 23.

The FR placement surface 24 is provided around the wafer placement surface 22 and has an annular shape. The FR placement surface 24 is located at a lower level than the wafer placement surface 22. The FR placement surface 24 is designed to receive an annular focus ring 60. The focus ring 60 is made of, for example, Si. In an upper part of the inner sidewall of the focus ring 60 is provided with circumferential groove 62, with which the focus ring 60 avoids touching the wafer W.

The cooling plate 30 is formed of, for example, a metal material or a metal-ceramic composite material. Examples of the metal material include Al, Ti, Mo, and alloys of them. Examples of the metal-ceramic composite material include metal matrix composites (MMC) and ceramic matrix composites (CMC). Specific examples of the composite materials include a material containing Si, SiC, and Ti (may be referred to as SisiCTi), a material containing a SiC porous body impregnated with Al and/or Si, and an Al₂O₃—TiC composite material. The cooling plate 30 internally has a refrigerant flow path 32 through which a refrigerant can circulate. As illustrated in FIG. 2, the refrigerant flow path 32 extends from one end (an inlet 32 in) to the other end (an outlet 32out) in a one-stroke pattern over the entire surface of the ceramic plate 20 in plan view. The refrigerant flow path 32 of this embodiment extends in a spiral shape in plan view. Such a cooling plate 30 can be produced, for example, by diffusion bonding multiple layered members. A refrigerant is supplied from a refrigerant circulator (not illustrated) through the inlet 32 in of the refrigerant flow path 32 and flows through the refrigerant flow path 32 to be discharged through the outlet 32out of the refrigerant flow path 32 back to the refrigerant circulator. The refrigerant circulator can adjust the refrigerant to the desired temperature. The refrigerant is preferably in the form of liquid and preferably has electrical insulating properties. Examples of the electrically insulating liquid include a fluorinated inert liquid. The cooling plate 30 has an insulating hole 40 located beside the refrigerant flow path 32. The insulating hole 40 extends from a lower surface 38 of the cooling plate 30 to a ceiling 47 located higher than 2/3 of the height of the refrigerant flow path 32 from the bottom. The insulating hole 40 is hollow and may be filled with a gas such as air or He or may be a vacuum.

The bonding layer 50 bonds the lower surface 28 of the ceramic plate 20 and the upper surface 36 of the cooling plate 30 to each other. The bonding layer 50 may be a metal layer formed of solder or a metal brazing material, for example, or a resin layer formed of a resin adhesive.

The insulating hole 40 will be described with reference to FIGS. 3 to 5. As illustrated in FIG. 3, the insulating hole 40 in the form of groove is located between passages of the refrigerant flow path 32 along the flow path with a space from the flow path. Furthermore, as illustrated in FIGS. 4 and 5, the insulating hole 40 opens in the lower surface 38 of the cooling plate 30 and extends straight from the opening to the ceiling 47. The ceiling 47 of the insulating hole 40 is located higher than the plane located at 2h/3 of the height of the refrigerant flow path 32 from the bottom 34 (virtual plane S indicated by the two-dot-dash line), where h represents the height of the refrigerant flow path 32. In this embodiment, the ceiling 47 of the insulating hole 40 is flat and on a plane at the same height as the ceiling 33 of the refrigerant flow path 32 (virtual plane T indicated by the two-dot-dash line). A distance a between the ceiling 47 of the insulating hole 40 and the upper surface 36 of the cooling plate 30 is, for example, 1 mm or more and 15 mm or less. The distance a may be the same or different from the distance i between the ceiling 33 of the refrigerant flow path 32 and the upper surface 36 of the cooling plate 30. The distance i between the ceiling 33 of the refrigerant flow path 32 and the upper surface 36 of the cooling plate 30 is, for example, 2 mm or more and 5 mm or less. The width b of the insulating hole 40 may be appropriately set so that the thickness d of a portion between the insulating hole 40 and the refrigerant flow path 32 is greater than or equal to a predetermined thickness (e.g., 2 mm or more). For example, the width b is 2 mm or more and 16 mm or less. The distance j between the passages of the refrigerant flow path 32 is, for example, 6 mm or more and 20 mm or less. The length c of the insulating hole 40 is, for example, 5 mm or more and 300 mm or less. The length c of the insulating holes 40 may be the length in the extending direction of the refrigerant flow path 32 (longitudinal direction), and the width b of the insulating hole 40 may be the length in the direction perpendicular to the longitudinal direction and the height direction. The heat extraction performance can be controlled, for example, by adjustment of the volume of the insulating hole 40, which is achieved by the adjustment of the above-described distance a, the width b, and the length c, for example.

Now, an exemplary usage of the wafer placement table 10 will be described. The wafer placement table 10 is fixed to the inside of a semiconductor-processing chamber, which is not illustrated. The focus ring 60 is placed on the FR placement surface 24, and a wafer W is placed on the wafer placement surface 22. In this state, a direct-current voltage is applied to the electrostatic electrode 23, whereby the wafer W is attracted to the wafer placement surface 22. Meanwhile, a heat conductive gas (such as He gas) is supplied to a gas passageway (a passageway extending from the lower surface of the cooling plate 30 to the wafer placement surface 22), which is not illustrated but is provided in the wafer placement table 10. Accordingly, the space enclosed by the lower surface of the wafer W and the seal band on the wafer placement surface 22 is filled with the gas. Thus, heat is to be conducted in a favorable manner between the wafer W and the wafer placement surface 22. Then, a predetermined vacuum atmosphere (or a reduced-pressure atmosphere) is produced inside the chamber. Furthermore, while a process gas is supplied from a showerhead provided at the ceiling of the chamber, an RF voltage is applied to the cooling plate 30. Accordingly, plasma is generated between the wafer W and the showerhead. With the plasma, CVD film deposition or etching is performed on the wafer W.

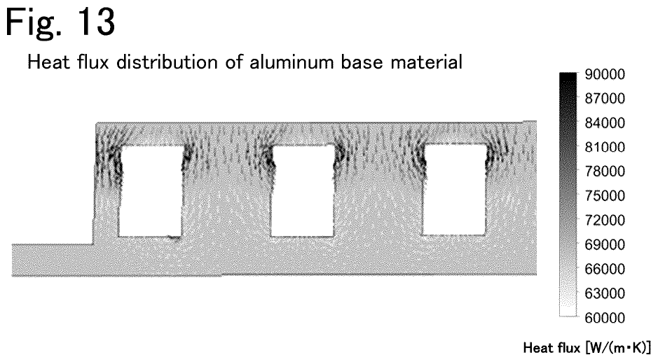

When a wafer W is processed with plasma in this way, the wafer W is heated to high temperature by the heat from plasma. The refrigerant, which flows in the refrigerant flow path 32 of the wafer placement table 10, extracts heat from the wafer W through the ceramic plate 20, the bonding layer 50, and the cooling plate 30. The heat extraction is expected to allow the wafer W to have a desired temperature distribution. When the wafer placement table 10 receives heat at the wafer placement surface 22, the refrigerant in the refrigerant flow path 32 extracts heat through the ceiling 33 of the refrigerant flow path 32 and also through the side surface 35 of the refrigerant flow path 32. The heat flux in the cooling plate 30 at that time tends to be relatively large at a portion located beside the refrigerant flow path 32 and higher than 2/3 of the height of the refrigerant flow path 32 from the bottom, depending on the material of the cooling plate 30. This point will be explained with reference to FIG. 13. FIG. 13 is an explanatory view illustrating an example of heat flux distribution in a vertical cross-section of a cooling plate (without an insulating hole). Specifically, FIG. 13 is a contour diagram illustrating an example of heat flux in a cooling plate in which the material of the cooling plate is Al, the wafer placement surface is 80° C., and a refrigerant of −10° C. flows. FIG. 13 shows that the heat flux in the cooling plate tends to be relatively large at a portion located beside the refrigerant flow path and higher than 2/3 of the height of the refrigerant flow path from the bottom. When the portion where the heat flux is large has the insulating hole 40, the hole functions as an insulating layer and efficiently reduces heat extraction around the insulating hole 40. Thus, the insulating hole 40 formed at a position corresponding to a portion of the wafer placement surface 22 where the temperature is lower than a desired temperature when the insulating hole 40 is not present, for example, can reduce heat extraction at the portion, bringing the temperature distribution in the wafer placement surface 22 closer to the desired temperature distribution.

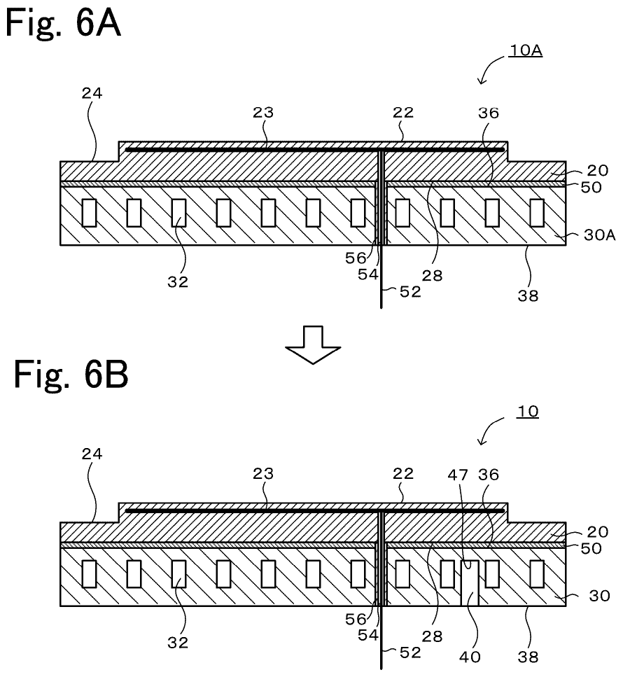

Next, an example of a process of producing the wafer placement table 10 will be described with reference to FIGS. 6A and 6B. First, a wafer placement table before adjustment 10A is provided that includes a ceramic plate 20, a cooling plate before adjustment 30A, and a bonding layer 50 (FIG. 6A). In the wafer placement table before adjustment 10A, the ceramic plate 20 and the bonding layer 50 are the same as the ceramic plate 20 and the bonding layer 50 of the above-described wafer placement table 10, and the cooling plate before adjustment 30A is the same as the cooling plate 30 except that it does not have an insulating hole 40. Next, the wafer placement table before adjustment 10A is subjected to an adjustment process that includes forming the insulating hole 40 extending from the lower surface of the cooling plate before adjustment 30A to the ceiling 47 located higher than 2/3 of the height of the refrigerant flow path 32 from the bottom (FIG. 6B). In this way, in the wafer placement table before adjustment 10A, heat extraction can be readily reduced by simply forming the insulating hole 40 in the lower surface 38 of the cooling plate before adjustment 30A.

Before the adjustment process, a measurement process may be performed to measure the temperature distribution in the wafer placement surface 22 of the wafer placement table before adjustment 10A. In the adjustment process, based on the temperature distribution measured in the measurement process, the insulating hole 40 may be formed at a position corresponding to the portion of the wafer placement surface 22 where the temperature is lower than a desired temperature. This enables the position and the shape of the insulating hole 40 to be adjusted based on the measured temperature distribution, allowing easy and accurate adjustment of the heat extraction level.

In the above-described wafer placement table 10, the cooling plate 30 includes the insulating hole 40 located beside the refrigerant flow path 32, and the insulating hole 40 extends from the lower surface 38 of the cooling plate 30 to the ceiling 47 located higher than 2/3 of the height of the refrigerant flow path from the bottom. Thus, for example, if the wafer placement surface 22 has a portion where the temperature is lower than a desired temperature when the insulating hole 40 is not present, the insulating hole 40 formed at a position corresponding to the portion can reduce heat extraction at the portion, bringing the temperature distribution in the wafer placement surface 22 closer to the desired temperature distribution.

The distance a between the upper surface 36 of the cooling plate 30 and the ceiling 47 of the insulating hole 40 is preferably 1 mm or more. When the distance is 1 mm or more, the wafer placement table 10 is less likely to be damaged.

Furthermore, the cooling plate 30 preferably has a thermal conductivity of 100 W/(m·K) or higher. As the thermal conductivity of the cooling plate 30 increases, the heat flux at a portion located beside the refrigerant flow path 32 and higher than 2/3 of the height of the refrigerant flow path 32 from the bottom (formation portion of the insulating hole 40) tends to be higher than that at the other portions, allowing the insulating hole 40 to exhibit high efficiency in reducing heat extraction. Al and Al alloys, which have the thermal conductivities of 150 to 200 W/(m·K), are preferable as materials of the cooling plate 30. If the cooling plate 30 is formed of Al or Al alloy, the bonding layer 50 is often a resin layer.

Furthermore, the insulating hole 40 is preferably located at a position corresponding to a portion of the wafer placement surface 22 where the temperature is locally low when the insulating hole 40 is not present. This can reduce heat extraction at the portion of the wafer placement surface 22 where the temperature is locally low, improving the heat uniformity of the wafer placement surface 22. The portion of the wafer placement surface 22 where the temperature is locally low when the insulating hole 40 is not present is a portion around the inlet 32in of the refrigerant flow path 32 or a portion between passages of the refrigerant flow path 32 that is narrowed due to the arrangement of the terminal hole 54, for example.

The present invention is not limited to the above embodiment in any way and can be embodied in various ways within the technical scope thereof, of course.

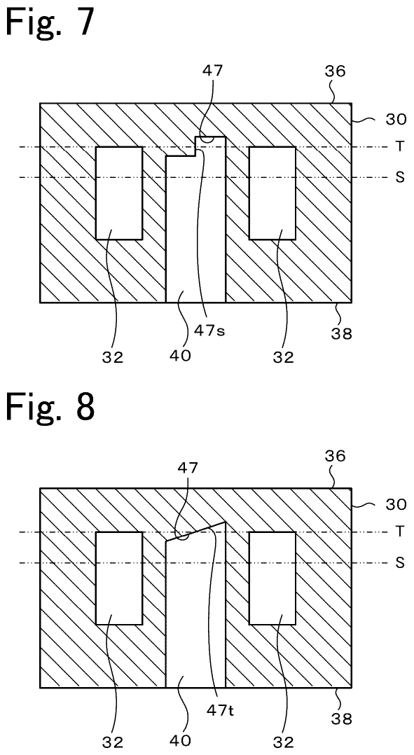

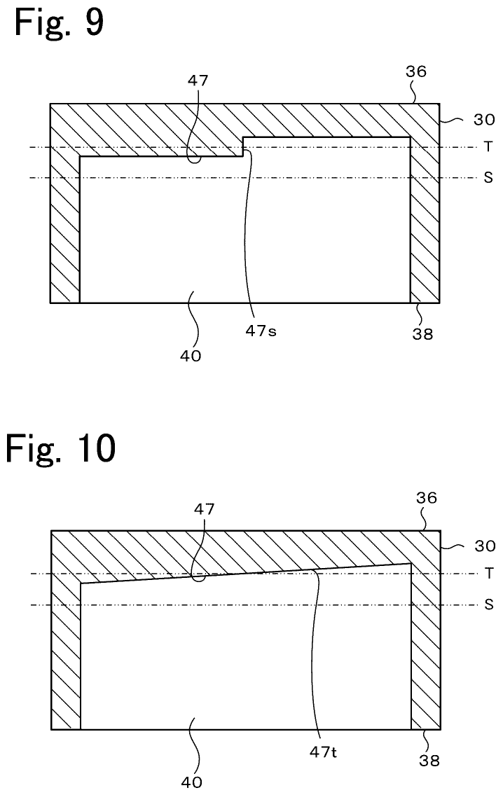

For example, in the above-described embodiment, the ceiling 47 of the insulating hole 40 is flat, but the ceiling 47 may be non-flat. For example, as illustrated in FIG. 7, the ceiling 47 may have a step 47s in the width direction, or as illustrated in FIG. 8, the ceiling may have a slope 47t in the width direction. Alternatively, for example, as illustrated in FIG. 9, the ceiling 47 may have a step 47s in the length direction, or as illustrated in FIG. 10, the ceiling 47 may have a slope 47t in the length direction. When the insulating hole 40 has a flat ceiling 47, there may be a portion where heat extraction is not sufficiently reduced, or there may be a portion where less heat extraction is required to have a slightly higher temperature. In such cases, the portion (where further less heat extraction is required) of the ceiling 47 is raised higher than the other portions, so that the temperature distribution in the wafer placement surface 22 is brought further closer to the desired temperature distribution. The above-described embodiment includes one

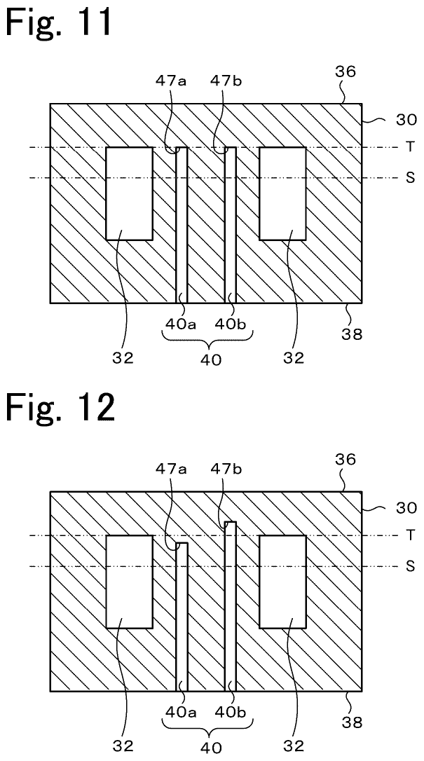

insulating hole 40 between the passages of the refrigerant flow path 32 (the distance j in FIG. 4) but may include multiple insulating holes. The holes may have the same or different ceiling heights. As illustrated in FIGS. 11 and 12, the insulating hole 40 may include two insulating holes 40a and 40b between the passages of the refrigerant flow path 32, for example. The ceiling 47a of the insulating hole 40a and the ceiling 47b of the insulating hole 40b may have the same height as in FIG. 11 or may have different heights as in FIG. 12. When the number of multiple insulating holes 40 between the passages of the refrigerant flow path 32 is two or more, the insulating holes 40 can be arranged to avoid the through hole or the like in the cooling plate 30 and can also reduce heat extraction around the hole. Even when the insulating holes 40 having the same ceiling height are provided, there may be a portion where heat extraction is not sufficiently reduced, or there may be a portion where less heat extraction is required to have a slightly higher temperature. In such cases, the multiple insulating holes 40 may have different ceiling heights. The temperature distribution in the wafer placement surface 22 can be brought further closer to the desired temperature distribution by raising the portion (where further less heat extraction is required) of the ceiling 47 (the ceiling 47bin FIG. 12).

The above-described embodiment includes one insulating hole 40 in the length direction of the refrigerant flow path 32 but may include two or more insulating holes.

In the above-described embodiment, the insulating hole 40 is located between the passages of the refrigerant flow path 32, but the insulating hole may be located outwardly from the outermost passage, for example, as long as the insulating hole is located beside the refrigerant flow path 32.

The above-described embodiment includes one refrigerant flow path 32 but may include two or more refrigerant flow paths 32. In such a case, the insulating hole 40 may be located between passages of one refrigerant flow path 32 or between two or more refrigerant flow paths 32.

In the above-described embodiment, the insulating hole 40 is in the form of groove extending along the refrigerant flow path 32 but may be in the form of through hole having nearly equal width and length. Furthermore, the insulating hole 40 is curved along the refrigerant flow path 32 but may be straight.

In the above-described embodiment, the insulating hole 40 is hollow, but an insulating material may fill the insulating hole 40. However, when the filling with the insulating material is not performed, the insulating layer can be added simply by machining to form the insulating hole.

Thus, this is an easier way to reduce heat extraction and preferable.

According to the above embodiment, the electrostatic electrode 23 is provided inside the ceramic plate 20 at such a position as to face the wafer placement surface 22. In addition, an FR attraction electrode for electrostatically attracting the focus ring 60 may be provided inside the ceramic plate 20 at such a position as to face the FR placement surface 24.

The above embodiment relates to an exemplary case where the ceramic plate 20 has the wafer placement surface 22 and the FR placement surface 24. However, the present invention is not particularly limited to such an embodiment. For example, the ceramic plate 20 may be a plate having the wafer placement surface 22 but no FR placement surface 24.

According to the above embodiment, the refrigerant flow path 32 has a swirling shape in plan view. However, the present invention is not particularly limited to such an embodiment. For example, the refrigerant flow path 32 may have a zigzag shape in plan view.

The above embodiment relates to an exemplary case where the wafer placement table 10 includes the ceramic plate 20 provided thereinside with the electrostatic electrode 23. However, the present invention is not particularly limited to such an embodiment. For example, the ceramic plate 20 may be provided thereinside with a heater electrode (resistance heating element) or a plasma-generating electrode (RF electrode) in replacement of or in addition to the electrostatic electrode 23.

In the above embodiment, the wafer placement table 10 may have a plurality of lift pin holes each extending through the wafer placement table 10 from top to bottom. Such lift pin holes are holes intended to receive lift pins with which the wafer W is moved up and down relative to the wafer placement surface 22. In the plan view of the wafer placement surface 22, the plurality of lift pin holes are arranged, for example, at regular intervals along a circle concentric to the wafer placement surface 22.

### EXAMPLE

Hereinafter, an example of the present invention

will be described. However, the following example is not intended to limit the invention.

### Example 1

The wafer placement tables before and after adjustment 10A and 10 were examined for the temperature distribution in the wafer placement surface 22 by simulating the case where the wafer placement surface 22 receives heat. Specifically, the temperature distribution in the wafer placement surface 22 was examined under circumstances where an external heater generates heat so that the steady-state temperature of the wafer placement surface 22 becomes about 80° C. and a refrigerant of −10° C. circulates in the refrigerant flow path 32. The cooling plates before and after adjustment 30A and 30 were formed of Al. In the wafer placement table after adjustment 10, the ceiling 47 of the insulating hole 40 is located at the same height as the ceiling 33 of the refrigerant flow path 32, the width b of the insulating hole 40 is 8 mm, the length c of the insulating hole 40 is 100 mm, and the thickness d between the insulating hole 40 and the refrigerant flow path 32 is 3 mm. Then, the wafer placement tables before and after adjustment 10A and 10 were compared in terms of the temperature distribution in the wafer placement surface 22. The temperature of the portion of the wafer placement surface 22 over the insulating hole 40 was higher in the wafer placement table after adjustment 10 than in the wafer placement table before adjustment 10A by about 1.5° C., indicating that the presence of the insulating hole 40 can reduce heat extraction around it. This showed that the insulating hole 40 formed at a position corresponding to a portion of the wafer placement surface 22 where the temperature is lower than a desired temperature when the insulating hole 40 is not present can reduce heat extraction at the portion, bringing the temperature distribution in the wafer placement surface 22 closer to the desired temperature distribution.

International Application No. PCT/JP2023/033249, filed on Sep. 12, 2023, is incorporated herein by reference in its entirety.

What is claimed is:

1. A wafer placement table comprising:
a ceramic plate having a wafer placement surface on its upper surface;
a cooling plate on a lower surface of the ceramic plate;
a refrigerant flow path in the cooling plate; and
an insulating hole located beside the refrigerant flow path in the cooling plate and extending from a lower surface of the cooling plate to a ceiling located higher than 2/3 of a height of the refrigerant flow path from its bottom.

2. The wafer placement table according to claim 1, wherein a distance between the ceiling of the insulating hole and an upper surface of the cooling plate is 1 mm or more.

3. The wafer placement table according to claim 1,
wherein the insulating hole is located between passages of the refrigerant flow path.

4. The wafer placement table according to claim 1,
wherein the ceiling of the insulating hole has a step or a slope.

5. The wafer placement table according to claim 1, wherein the cooling plate has a thermal conductivity of 100 W/(m·K) or higher.

6. The wafer placement table according to claim 1,
wherein the insulating hole is located at a position corresponding to a portion of the wafer placement surface where a temperature is locally low when the insulating hole is not present.
